(19) United States
(12) Patent Application Publication
(10) Pub. No.: US 2019/0088901 A1
(43) Pub. Date: Mar. 21, 2019

(54) ENCAPSULATION METHOD FOR OLED THIN FILM, OLED THIN FILM ENCAPSULATION STRUCTURE AND OLED STRUCTURE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wei YU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/741,127

(22) PCT Filed: Oct. 24, 2017
(86) PCT No.: PCT/CN2017/107475

§ 371 Date: Sep. 27, 2018

(30) Foreign Application Priority Data
Sep. 20, 2017 (CN) 201710855074.7

(51) Int. Cl. H01L 51/52; H01L 51/56

(52) U.S. Cl. CPC H01L 51/5237; H01L 51/0094; H01L 51/56

(57) ABSTRACT

The present application discloses an encapsulation method for an OLED thin film, including the steps of: depositing a first inorganic material film layer on a substrate provided with an OLED device, wherein the first inorganic material film completely covers the OLED device; gradually adjusting a first control parameter to control depositing a first organic material film layer on the first inorganic material film layer; depositing a second inorganic material film layer on the first organic material film layer; gradually adjusting a second control parameter to control depositing a second organic material film layer on the second inorganic material film layer, to make hardness of the first and the second organic material film layer gradually increased in a direction from near to far from the OLED device; and depositing a third inorganic material film layer on the second organic material film layer.

### RELATED APPLICATIONS

The present application is a National Phase of International Application Number PCT/CN2017/107475, filed Oct. 24, 2017, and claims the priority of China Application CN 201710855074.7, filed Sep. 20, 2017.

### FIELD OF THE DISCLOSURE

The disclosure relates to a display technical field, and more particularly to an encapsulation method for OLED thin film, an OLED thin film encapsulation structure and an OLED structure.

### BACKGROUND

OLED displays are a new generation of displays, by forming an organic thin film on an OLED substrate, wherein the organic thin film is disposed between a cathode electrode and an anode electrode, applying a voltage to the two electrodes, the organic thin film can emit light.

Currently, the encapsulation methods for OLED are generally divided into two types: glass encapsulation and film encapsulation, wherein OLED thin film encapsulation mainly adopts a laminated structure of a barrier layer and a buffer layer disposed on an OLED device, for example, in a five-layer thin film encapsulation structure, from bottom to top, the first, third and fifth layers are barrier layers, and the second and fourth layers are buffer layers.

Wherein, the barrier layer adapts inorganic materials, such as SiNₓ, SiOₓ, SiON, etc.; the buffer layer usually adapts organic or organic-like materials. The barrier layer functions as a barrier to water vapor and oxygen, to prevent darkening caused by water vapor or oxygen intruding into the OLED device. The buffer layer mainly serves to eliminate stress, gaps and voids between the two barrier layers, and also functions as a flat, in order to facilitate the subsequent growth of inorganic films.

In the conventional technology, the thin film encapsulation is often performed by adapting plasma enhanced chemical vapor deposition, PECVD in combination with Inkjet printing, IJP, wherein the PECVD process is used to form the barrier layer that is, the inorganic material film). The IJP process is used to print the buffer layer (that is, the organic material film layer). In this process, the thickness of the organic material film layer is generally 4-8 μm; if the thickness is less than 4 μm, mura phenomenon easily occurs (that is, uneven luminance of the display). The thicker organic material film layer increases the processing time and the material cost, and the IJP machine and material are expensive, and the leakage and mura are easy to occur. In addition, in the entire process, it also needs to be back and forth between the PECVD machine and IJP machine and capable to complete the thin film encapsulation process.

Therefore, there is a need for an OLED thin film encapsulation process that is simple in process, low in cost and good in film formation.

### SUMMARY

The technical problem to be solved by the present application is to provide an encapsulation method for an OLED thin film, a structure and an OLED structure, to achieve better encapsulation effect and prolong the lifetime of the OLED device.

In order to solve the above technical problem, one aspect of the embodiments of the present application provides an encapsulation method for an OLED thin film, including the steps of:

Depositing a first inorganic material film layer on a substrate provided with an OLED device, wherein the first inorganic material film completely covers the OLED device;

Gradually adjusting a first control parameter to control depositing a first organic material film layer on the first inorganic material film layer, to make a hardness of the first organic material film layer gradually increased in a direction from near to far from the OLED device;

Depositing a second inorganic material film layer on the first organic material film layer;

Gradually adjusting a second control parameter to control depositing a second organic material film layer on the second inorganic material film layer, to make a hardness of the second organic material film layer gradually increased in a direction from near to far from the OLED device; and

Depositing a third inorganic material film layer on the second organic material film layer.

Wherein the first control parameter includes: a first radio frequency power and a first N₂O/HMDSO value used in a deposition process, wherein the first N₂O/HMDSO value is a first flow ratio of nitrous oxide to vaporized hexamethyldisiloxane;

The step of gradually adjusting the first control parameter to control depositing the first organic material film layer on the first inorganic material film layer including:

Controlling depositing of an organic material on the second inorganic material film layer with the first radio frequency power and the first N₂O/HMDSO value; and

Gradually increasing the first radio frequency power or/and the first N₂O/HMDSO value, and controlling to continue depositing the organic material on the second inorganic material film until to form the first organic material film with a predetermined thickness.

Wherein the second control parameter includes: a second radio frequency power and a second N₂O/HMDSO value used in a deposition process, wherein, the second N₂O/HMDSO value is a second flow ratio of nitrous oxide to vaporized hexamethyldisiloxane;

The step of gradually adjusting the second control parameter to control depositing the second organic material film layer on the second inorganic material film layer including:

Controlling depositing of an organic material on the second inorganic material film layer with the second radio frequency power and the second N₂O/HMDSO value; and

Gradually increasing the second radio frequency power and the second N₂O/HMDSO value, and controlling to continue depositing the organic material on the second inorganic material film until to form the second organic material film with a predetermined thickness.

Wherein, further including:

Gradually adjusting a third control parameter to control depositing a third organic material film layer on the third inorganic material film layer, to make the a hardness of the third organic material film layer gradually increased in a direction from near to far from the OLED device; and

Depositing a fourth inorganic material film layer on the third organic material film layer.

Wherein the third control parameter includes: a third radio frequency power and a third N₂O/HMDSO value used in a deposition process, wherein, the third N₂O/HMDSO value is a third flow ratio of nitrous oxide to vaporized hexamethyldisiloxane;

The step of gradually adjusting the third control parameter to control depositing the third organic material film layer on the third inorganic material film layer including:

Controlling depositing of an organic material on the third inorganic material film layer with the third radio frequency power and the third N₂O/HMDSO value; and

Gradually increasing the third radio frequency power and/or the third N₂O/HMDSO value, and controlling to continue depositing the organic material on the third inorganic material film until to form the third organic material film with a predetermined thickness.

Wherein material used for the organic material film layers is hexamethyldisiloxane material, materials of the first inorganic material film layer, the second inorganic material film layer, the third inorganic material film layer and the fourth inorganic material film layer are all adapting SiNₓ, SiOₓ or SiON material, and the deposition process adopts a chemical vapor deposition method.

Accordingly, another aspect of the embodiments of the present application further provides an OLED thin film encapsulation structure, the OLED thin film encapsulation structure is obtained by the foregoing method, wherein the OLED thin film encapsulation structure includes:

A first inorganic material film layer deposited on a substrate having an OLED device, wherein a hardness of the first inorganic material film layer is gradually increased in a direction from near to far from the OLED device;

A second inorganic material film layer deposited on the first organic material film layer;

A second organic material film layer deposited on the second inorganic material film layer, wherein a hardness of the second organic material film layer is gradually increased in a direction from near to far from the OLED device; and

A third inorganic material film layer deposited on the second organic material film layer.

Wherein, further including:

A third organic material film layer deposited on the third inorganic material film layer, wherein a hardness of the third organic material film layer is gradually increased in a direction from near to far from the OLED device; and

A fourth inorganic material film layer deposited on the third organic material film layer.

Wherein material used for the organic material film layers is hexamethyldisiloxane material, materials of the first inorganic material film layer, the second inorganic material film layer, the third inorganic material film layer and the fourth inorganic material film layer are all adapting SiNₓ, SiOₓ or SiON material, the deposition process adopts a chemical vapor deposition method, and each thickness of the first inorganic material film layer, the second inorganic material film layer, the third inorganic material film layer and the fourth inorganic material film layer is 1.5-2 μm.

Accordingly, still another aspect of the embodiments of the present application provides an OLED structure including a substrate and an OLED device formed on the substrate, wherein an OLED thin film encapsulation structure is further formed by using a chemical vapor deposition method on the OLED device.

The implementation of the embodiments of the present application has the following beneficial effects:

By adapting the HMDSO material for forming the organic material film layer, and gradually adjusting the control parameters, the deposition to form the organic material film layer is controlled, so that the hardness of the organic material film layer is gradually increased along the direction from near to far from the OLED device; that is, in each organic material film layer, in the position closer to the OLED device, the lower radio frequency power and N₂O/HMDSO values are adapted, to obtain softer film values, with better liquidity; while in the position far from the OLED devices, the higher radio frequency power and N₂O/HMDSO values are adapted, to obtain a harder film values, and better flatness, to meet the bidirectional requirements for HMDSO coverage defects, particles and surface flatness; thus achieving better encapsulation effect and extend the lifetime of the OLED devices;

In the meantime, since the chemical vapor deposition process is used in formation of the inorganic material film and the organic material film, the same machine can be used to realize the entire film encapsulation process, which can improve the encapsulation efficiency and reduce the cost.

### BRIEF DESCRIPTION OF THE DRAWINGS

To describe the technical solutions in the embodiments of the present application or in the conventional technology more dearly, the following briefly introduces the accompanying drawings required for describing the embodiments or the conventional technology. Apparently, the accompanying drawings in the following description merely show some embodiments of the present application. For those skilled in the art, other drawings may be obtained based on these drawings without any creative work.

FIG. 1 is a main process flow diagram of an encapsulation method for an OLED thin film in one embodiment provided by the present application;

FIG. 2 is a schematic structural view of an OLED structure in one embodiment provided by the present application;

FIG. 3a and FIG. 3b are a partial SEM top view and a side view of the organic material film obtained by using the lower control parameters in the present application, respectively; and

FIG. 4a and FIG. 4b are a partial SEM top view and a side view of the organic material film obtained by using higher control parameters in the present application, respectively.

### DETAILED DESCRIPTION OF PREFERRED EMBODIMENTS

The technical solutions in the embodiments of the present application will be described clearly and completely below with reference to the accompanying drawings in the embodiments of the present application. Apparently, the described embodiments are merely some but not all embodiments of the present application. All other embodiments obtained by a person of ordinary skill in the art based on the embodiments of the present application without creative efforts shall fall within the protection scope of the present application.

Here, it should also be noted that in order to avoid obscuring the present application by unnecessary details, only the structures and/or processing steps that are closely related to the solutions according to the present application are shown in the drawings, other details of the application are of little relevance.

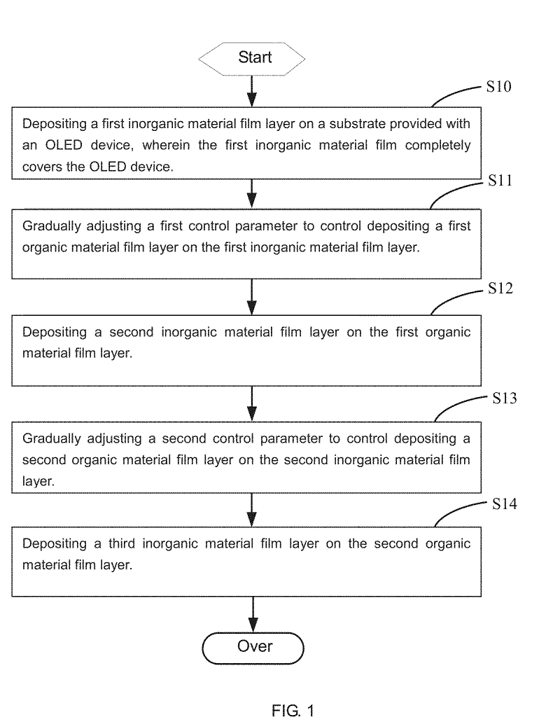

As shown in FIG. 1, a main process flow diagram of one embodiment of the encapsulation method for the OLED thin film according to the present application is shown. In this embodiment, the method includes the following steps:

Step S10, depositing a first inorganic material film layer on the substrate provided with the OLED device, wherein the first inorganic material film completely covers the OLED device;

In step S11, gradually adjusting a first control parameter to control depositing of the first organic material film layer on the first inorganic material film layer to make a hardness of the first organic material film layer gradually increased in a direction from near to far from the OLED device, specifically, the first control parameter includes: a first radio frequency power and a first N₂O/HMDSO value used in the deposition process, wherein the first N₂O/HMDSO value is the first flow ratio of nitrous oxide to vaporized hexamethyldisiloxane, for example, in one example, the first N₂O/HMDSO value is 2, that is, the flow volume of the N₂O is twice as the flow volume of the HMDSO in the process, the first Radio frequency power is 10 KV; and the step S11 includes:

Controlling to deposit of the organic material on the second inorganic material film layer with the first radio frequency power and the first N₂O/HMDSO value;

Gradually increasing the first radio frequency power and the first N₂O/HMDSO value, and controlling to continue depositing the organic material on the second inorganic material film until to form the first organic material film with a predetermined thickness (1.5-2 μm), for example, in one embodiment, the first N₂O/HMDSO value is increased by 0.5 for each time, the first radio frequency power is increased by 1 KV each time. The above is only an example and not a limitation, and the above added value may be different in different application scenarios.

Step S12, depositing a second inorganic material film layer on the first organic material film layer;

Step S13, gradually adjusting the second control parameter to control depositing a second organic material film layer on the second inorganic material film layer to make a hardness of the second organic material film layer gradually increased in a direction from near to far from the OLED device;

Specifically, the second control parameter includes: a second radio frequency power and a second N₂O/HMDSO value used in the deposition process, wherein, the second N₂O/HMDSO value is the second flow ratio of nitrous oxide to vaporized hexamethyldisiloxane, the step 13 includes:

Controlling to deposit of the organic material on the second inorganic material film with the second radio frequency power and the second N₂O/HMDSO flow ratio;

Gradually increasing the second radio frequency power and the second N₂O/HMDSO flow ratio, and controlling to continue depositing the organic material on the second inorganic material film until to form the second organic material film with a predetermined thickness (eg, 1.5-2 μm).

Step S14, depositing a third inorganic material film layer on the second organic material film layer;

Wherein, it should be understood that, in different embodiments, the first radio frequency power may be the same as or different from the second radio frequency power; the first N₂O/HMDSO value may be the same as or different from the second N₂O/HMDSO value.

Specifically, a material used for the first organic material film layer and the second organic material film layer is HMDSO (hexamethyldisiloxane) material, and the deposition process adopts a chemical vapor deposition method. Wherein, in one embodiment, the HMDSO thin film is formed by introducing a heated and vaporized HMDSO that is in liquid form at room temperature with N₂O into a cavity, and generating a plasma to proceed a reaction.

Specifically, the material of the first inorganic material film layer, the second inorganic material film layer and the third inorganic material film layer are all adapting SiNₓ material. In other embodiments, a SiOₓ material or a SiON material may also be adapted, and the deposition process uses chemical vapor deposition process.

It can be understood that, in the embodiments provided by the present application, the chemical vapor deposition process is completely adopted, wherein the inorganic material film layer is made of SiNₓ material, and the organic material film layer is made of HMDSO material; the thickness of SiNₓ is generally 0.5-1 μm, the thickness of HMDSO is generally 1.5-2 μm; because the thickness of the HMDSO is thinner, it has better flexibility, higher transmittance, lower production costs. However, the thinner of the thickness of the HMDSO put forward higher requirements to cover defects, particle capabilities and surface flatness. In the present application, this requirement is met by using different process parameters for different layers.

According to the research, during the film formation process of the HMDSO, when the radio frequency power is lower, the HMDSO film will be softer, relatively speaking will be with more “liquidity”, and therefore the surface is prone to have wrinkles, when the radio frequency power is high, the film quality will be hard, the surface will be smooth.

Meanwhile, when the ratio of N₂O/HMDSO is low, the quality of HMDSO film is also soft. When the ratio of N₂O/HMDSO is high, the quality of HMDSO film is rigid.

Therefore, in the technical solutions disclosed in the present application, the above-mentioned film-forming characteristics are fully utilized, and the film forming process of each layer of HMDSO is divided into a plurality of steps. When filming is started, the radio frequency power and the N₂O/HMDSO value are set lower, making the film value to be soft, the use of its “liquidity” can better cover the gap and voids in the first inorganic material film; in the end to form the film, the radio frequency power and N₂O/HMDSO value is set high, to make the film value is more rigid, resulting in better surface flatness for subsequent formation of the inorganic material film; the intermediate step is followed by gradually increasing the radio frequency power or/and the N₂O/HMDSO value, so that the entire HMDSO film value gradually from soft to rigid, to meet two-way demand of the cover defects and particles ability at the same time, as well as the surface flatness, so as to achieve better encapsulation effect and extend the lifetime of OLED devices.

Further, in other embodiments, on the basis of the above steps, the method may further include the following steps:

Gradually adjusting a third control parameter, to control depositing a third organic material film layer on the third inorganic material film layer, to make a hardness of the third organic material film layer gradually increased in a direction from near to far from the OLED device, specifically, the third control parameter includes: a third radio frequency power and a third N₂O/HMDSO value, wherein the third N₂O/HMDSO value is the third flow ratio of nitrous oxide to vaporized hexamethyldisiloxane, the further includes:

Controlling the deposition of the organic material on the third inorganic material film layer with the third radio frequency power and the third N₂O/HMDSO value;

Gradually increasing the third radio frequency power or/and the N₂O/HMDSO value, and controlling to continue depositing the organic material on the third inorganic material film layer until to form the third organic material film layer with a predetermined thickness.

Depositing a fourth inorganic material film layer on the third organic material film after the third organic material film is formed;

Wherein, the organic material film layer is made of HMDSO material; the first inorganic material film layer, the second inorganic material film layer, the third inorganic material film layer, and the fourth inorganic material film layer all adopt SiNₓ, SiOₓ or SiON materials; the deposition process adopts the chemical vapor deposition method; the predetermined thickness is 1.5-2 μm.

Wherein, the third radio frequency power may be the same as or different from the first radio frequency power, and the third N₂O/HMDSO value may be the same or different from the first N₂O/HMDSO value.

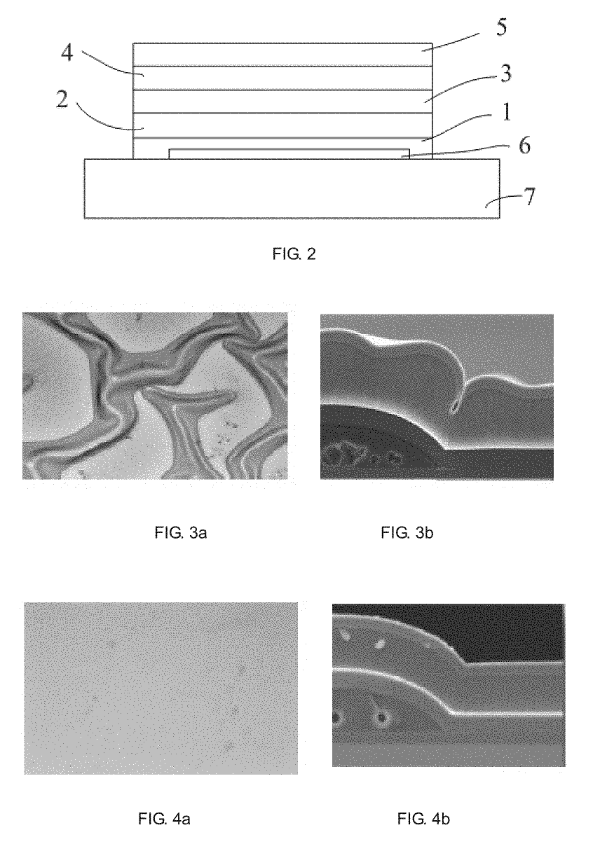

As shown in FIG. 2, a schematic structural view of one embodiment of an OLED structure provided by the present application is shown. In this embodiment, the OLED structure includes:

Substrate 7,

And an OLED device 6 formed on the substrate 7. The OLED device 6 may be the same structure as an existing OLED device. For example, the OLED device 6 may include an anode film, a hole injection film, a hole transport film layer, a light-emitting film layer, an electron-transporting film layer, an electron-injecting film layer and a metal cathode film layer will not be described in detail herein;

An OLED thin film encapsulation structure formed on the OLED device 6 by the chemical vapor deposition method.

Wherein, the OLED thin film encapsulation structure specifically includes:

At least two organic material film layers, the first organic material film layer 2 and the second material film layer 4 are shown in FIG. 2;

At least two inorganic material film layers, the first inorganic material film layer 1, the second inorganic material film layer 3, and the third inorganic material film layer 5 are shown in FIG. 2;

The single-layer organic material film layer and the single-layer inorganic material film layer are alternately disposed, and one of the inorganic material film layers needs to completely cover the OLED device 6 disposed on the substrate 7. As shown in FIG. 2, the first inorganic material film layer 1, the first organic material film layer 2, the second inorganic material film layer 3, the second organic material film layer 4 and the third inorganic material film layer 5 are sequentially disposed from the near-to-far direction of the OLED device 6;

Each of the at least two organic material film layers gradually increases in hardness in a direction from near to far from the OLED device, that is, the hardness of the first organic material film layer close to the first inorganic material film layer is smaller than the hardness close to the second inorganic material film layer, the other organic material film layers are similar with this, and will not be described in detail.

Specifically, in an embodiment, the organic material film layer is made of HMDSO material, the inorganic material film layer is made of SiNₓ material, in other embodiments, SiOₓ or SiON material are also used. The thickness of the inorganic material film layer is 0.5-1 μm; the thickness of the organic material film layer is 1.5-2 μm.

It can be understood that, the OLED thin film encapsulation structure in the present application is obtained by the encapsulation method for the OLED thin film in FIG. 1. Reference may be made to the foregoing description of FIG. 1 for more details.

Further, as shown in FIG. 3a and FIG. 3b, a partial top view and a side view of the organic material film layer obtained by using the lower control parameters in the present application and taken by a scanning electron microscope (SEM) are shown. FIG. 4a and FIG. 4b shows a partial top view and a side view of the organic material film obtained by using higher control parameters in the present application by SEM; it can be seen from the figures that the organic material film layer shown in FIG. 3a and FIG. 3b is relatively soft and has better “liquidity”, and therefore the surface is prone to have wrinkles; and as in contrast to the organic material film layer shown in FIG. 4a and FIG. 4b, the film quality is rigid and the surface is smoother, that is, the flatness is better.

It can be understood that, in other embodiments, more organic material films may be encapsulated, for example, a third organic material film layer is further deposited on the third inorganic material film layer 5, and then a fourth inorganic material film layer is further deposited on the third organic material film layer.

It can be understood that, in a specific embodiment, the present application provides an OLED thin film encapsulation structure, wherein the OLED thin film encapsulation structure includes:

A first inorganic material film layer deposited on a substrate having an OLED device, wherein the hardness of the first inorganic material film layer is gradually increased in a direction from near to far from the OLED device;

A second inorganic material film layer deposited on the first organic material film layer;

A second organic material film layer deposited on the second inorganic material film layer, wherein the hardness of the second organic material film layer is gradually increased in a direction from near to far from the OLED device;

A third inorganic material film layer deposited on the second organic material film layer.

Wherein further includes:

A third organic material film layer deposited on the third inorganic material film layer, wherein the hardness of the third organic material film layer is gradually increased in a direction from near to far from the OLED device;

A fourth inorganic material film layer deposited on the third organic material film layer.

Wherein, the organic material film layer is adapting hexamethyldisiloxane material; the first inorganic material film layer, the second inorganic material film layer, the third inorganic material film layer, and the fourth inorganic material film layer are all adopting SiNₓ, SiOₓ or SiON materials; the deposition process adopts the chemical vapor deposition method; the thickness of the first inorganic material film layer, the second inorganic material film layer, the third inorganic material film layer, and the fourth inorganic material film layer are 1.5-2 μm.

Accordingly, in still another aspect of the embodiments of the present application, the present application further provides an OLED structure, including a substrate and an OLED device formed on the substrate, the aforementioned OLED film encapsulation structure is further formed on the OLED device by chemical vapor deposition. Wherein, for the specific details of the OLED film encapsulation structure, reference may be made to the foregoing description.

The implementation of the embodiments of the present application has the following beneficial effects:

By adapting the HMDSO material for forming the organic material film layer, and gradually adjusting the control parameters, the deposition to form the organic material film layer is controlled, so that the hardness of the organic material film layer is gradually increased along the direction from near to far from the OLED device; that is, in each organic material film layer, in the position closer to the OLED device, the lower radio frequency power and N₂O/HMDSO values are adapted, to obtain softer film values, with better liquidity; while in the position far from the OLED devices, the higher radio frequency power and N₂O/HMDSO values are adapted, to obtain a harder film values, and better flatness, to meet the bidirectional requirements for HMDSO coverage defects, particles and surface flatness; thus achieving better encapsulation effect and extend the lifetime of the OLED devices;

In the meantime, since the chemical vapor deposition process is used in formation of the inorganic material film and the organic material film, the same machine can be used to realize the entire film encapsulation process, which can improve the encapsulation efficiency and reduce the cost.

It should be noted that, in this document, relational terms such as first and second are merely used to distinguish one entity or operation from another entity or operation, and do not necessarily require or imply that the entity or operation or any such actual relationship or order between. Also, the terms “include,” “comprise,” or any other variations thereof are intended to cover a non-exclusive inclusion such that a process, method, article, or apparatus that includes a list of elements includes not only those elements but also those that are not explicitly listed or other elements that are inherent to such process, method, article, or device. Without further limitations, an element limited by the statement “including a . . . ” does not exclude the existence of additional identical elements in the process, method, article, or apparatus that includes the element.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. An encapsulation method for an OLED thin film, comprising the steps of:
depositing a first inorganic material film layer on a substrate provided with an OLED device, wherein the first inorganic material film completely covers the OLED device;
gradually adjusting a first control parameter to control depositing a first organic material film layer on the first inorganic material film layer, to make a hardness of the first organic material film layer gradually increased in a direction from near to far from the OLED device;
depositing a second inorganic material film layer on the first organic material film layer;
gradually adjusting a second control parameter to control depositing a second organic material film layer on the second inorganic material film layer, to make a hardness of the second organic material film layer gradually increased in a direction from near to far from the OLED device; and
depositing a third inorganic material film layer on the second organic material film layer.

2. The encapsulation method for the OLED thin film according to claim 1, wherein the first control parameter comprises: a first radio frequency power and a first N₂O/HMDSO value used in a deposition process, wherein the first N₂O/HMDSO value is a first flow ratio of nitrous oxide to vaporized hexamethyldisiloxane;
the step of gradually adjusting the first control parameter to control depositing the first organic material film layer on the first inorganic material film layer comprising:
controlling depositing of an organic material on the second inorganic material film layer with the first radio frequency power and the first N₂O/HMDSO value; and
gradually increasing the first radio frequency power or/and the first N₂O/HMDSO value, and controlling to continue depositing the organic material on the second inorganic material film until to form the first organic material film with a predetermined thickness.

3. The encapsulation method for the OLED thin film according to claim 1, wherein the second control parameter comprises: a second radio frequency power and a second N₂O/HMDSO value used in a deposition process, wherein, the second N₂O/HMDSO value is a second flow ratio of nitrous oxide to vaporized hexamethyldisiloxane;
the step of gradually adjusting the second control parameter to control depositing the second organic material film layer on the second inorganic material film layer comprising:
controlling depositing of an organic material on the second inorganic material film layer with the second radio frequency power and the second N₂O/HMDSO value; and
gradually increasing the second radio frequency power and the second N₂O/HMDSO value, and controlling to continue depositing the organic material on the second inorganic material film until to form the second organic material film with a predetermined thickness.

4. The encapsulation method for the OLED thin film according to claim 3, further comprising:
gradually adjusting a third control parameter to control depositing a third organic material film layer on the third inorganic material film layer, to make the a hardness of the third organic material film layer gradually increased in a direction from near to far from the OLED device; and
depositing a fourth inorganic material film layer on the third organic material film layer.

5. The encapsulation method for the OLED thin film according to claim 4, wherein the third control parameter comprises: a third radio frequency power and a third N₂O/HMDSO value used in a deposition process, wherein, the third N₂O/HMDSO value is a third flow ratio of nitrous oxide to vaporized hexamethyldisiloxane;
the step of gradually adjusting the third control parameter to control depositing the third organic material film layer on the third inorganic material film layer comprising:
controlling depositing of an organic material on the third inorganic material film layer with the third radio frequency power and the third N₂O/HMDSO value; and
gradually increasing the third radio frequency power and/or the third N₂O/HMDSO value, and controlling to continue depositing the organic material on the third inorganic material film until to form the third organic material film with a predetermined thickness.

6. The encapsulation method for the OLED thin film according to claim 5, wherein material used for the organic material film layers is hexamethyldisiloxane material, materials of the first inorganic material film layer, the second inorganic material film layer, the third inorganic material film layer and the fourth inorganic material film layer are all adapting SiNₓ SiOₓ or SiON material, and the deposition process adopts a chemical vapor deposition method.

7. An OLED thin film encapsulation structure, comprising:
a first inorganic material film layer deposited on a substrate having an OLED device, wherein a hardness of the first inorganic material film layer is gradually increased in a direction from near to far from the OLED device;
a second inorganic material film layer deposited on the first organic material film layer;
a second organic material film layer deposited on the second inorganic material film layer, wherein a hardness of the second organic material film layer is gradually increased in a direction from near to far from the OLED device; and
a third inorganic material film layer deposited on the second organic material film layer.

8. The OLED thin film encapsulation structure according to claim 7, further comprising:
a third organic material film layer deposited on the third inorganic material film layer, wherein a hardness of the third organic material film layer is gradually increased in a direction from near to far from the OLED device; and
a fourth inorganic material film layer deposited on the third organic material film layer.

9. The OLED thin film encapsulation structure according to claim 8, wherein material used for the organic material film layers is hexamethyldisiloxane material, materials of the first inorganic material film layer, the second inorganic material film layer, the third inorganic material film layer and the fourth inorganic material film layer are all adapting SiNₓ, SiOₓ or SiON material, the deposition process adopts a chemical vapor deposition method, and each thickness of the first inorganic material film layer, the second inorganic material film layer, the third inorganic material film layer and the fourth inorganic material film layer is 1.5-2 μm.

10. An OLED structure, comprising: a substrate and an OLED device formed on the substrate, an OLED thin film encapsulation structure further formed on the OLED device by using a chemical vapor deposition method, wherein the OLED thin film encapsulation structure comprises:
a first inorganic material film layer deposited on a substrate having an OLED device, wherein a hardness of the first inorganic material film layer is gradually increased in a direction from near to far from the OLED device;
a second inorganic material film layer deposited on the first organic material film layer;
a second organic material film layer deposited on the second inorganic material film layer, wherein a hardness of the second organic material film layer is gradually increased in a direction from near to far from the OLED device; and
a third inorganic material film layer deposited on the second organic material film layer.

11. The OLED structure according to claim 10, further comprising:
a third organic material film layer deposited on the third inorganic material film layer, wherein a hardness of the third organic material film layer is gradually increased in a direction from near to far from the OLED device; and
a fourth inorganic material film layer deposited on the third organic material film layer.

12. The OLED structure according to claim 11, wherein material used for the organic material film layers is hexamethyldisiloxane material, materials of the first inorganic material film layer, the second inorganic material film layer, the third inorganic material film layer and the fourth inorganic material film layer are all adapting SiNₓ, SiOₓ or SiON material, the deposition process adopts a chemical vapor deposition method, and each thickness of the first inorganic material film layer, the second inorganic material film layer, the third inorganic material film layer and the fourth inorganic material film layer is 1.5-2 μm.
